(19) United States
(12) Patent Application Publication
(10) Pub. No.: US 2013/0307560 A1
(43) Pub. Date: Nov. 21, 2013

(54) SHEET SUBSTRATE, ELECTRONIC PART, ELECTRONIC APPARATUS, METHOD FOR TESTING ELECTRONIC PARTS, AND METHOD FOR MANUFACTURING ELECTRONIC PARTS

(71) Applicant: Seiko Epson Corporation, Tokyo (JP)

(72) Inventor: Kyo HORIE, Okaya (JP)

(73) Assignee: Seiko Epson Corporation, Tokyo (JP)

(21) Appl. No.: 13/892,541

(22) Filed: May 13, 2013

(30) Foreign Application Priority Data
May 15, 2012 (JP) 2012-111168

(51) Int. Cl. H05K 1/11; G01R 31/28; H05K 3/30; H05K 1/18

(52) U.S. Cl. CPC H05K 1/111; H05K 1/181; G01R 31/28; H05K 3/301
USPC 324/537; 174/261; 361/767; 29/837

(57) ABSTRACT

A sheet substrate includes a plurality of substrate regions arranged in a matrix, an integrated circuit disposed in each of the substrate regions, and a first implementation electrode and a second implementation electrode disposed in each of the substrate regions and electrically connected to the integrated circuit. The sheet substrate according to an embodiment of the invention further includes first terminals to each of which the first implementation electrodes arranged in a row of part of the substrate regions are connected in parallel to each other and second terminals to each of which the second implementation electrodes arranged in a column of part of the substrate regions and can activate an arbitrary one of the integrated circuits that is specified by selected ones of the first terminals and the second terminals.

### BACKGROUND

1. Technical Field

The present invention relates to a sheet substrate, an electronic part, an electronic apparatus, a method for testing electronic parts, and a method for manufacturing electronic parts, and particularly to a technology that allows a post-implementation test of an electronic device mounted on an electronic part to be readily performed.

2. Related Art

As a method for efficiently manufacturing an electronic part, what is called a multiple-piece manufacturing approach is used in related art. Specifically, a sheet substrate having a plurality of substrate regions is provided, and a piezoelectric resonator element, an IC, and other electronic devices are placed in each of the substrate regions. The sheet substrate is then divided along the boundaries between the substrate regions into individual pieces, which form individual electronic parts.

In the electronic part described above, the electronic devices mounted on the electronic part undergo an operation check and other verification steps in some cases. For example, when the electronic devices are a piezoelectric resonator element and an integrated circuit connected to the piezoelectric resonator element, a test probe is allowed to come into contact with a connection electrode electrically connected to the integrated circuit, and whether or not the piezoelectric resonator element oscillates or whether the resonant frequency, the CI value, and other parameters of the piezoelectric resonator element fall within appropriate ranges, or any other operation is tested in some cases. The test allows only electronic parts that pass the test to proceed to the following step.

To reduce the cost associated with an electronic part, it is necessary to increase the number of electronic parts manufactured per sheet substrate. Increasing the number of electronic parts, however, increases the degree of complication of the test on individual electronic parts.

JP-A-2004-328505 discloses a configuration in which a wiring line is drawn from a connection electrode in each substrate region, and the wiring lines are connected outside the substrate regions in parallel to each other, followed by a test of electronic parts by delivering electric power through the wiring lines connected in parallel to each other to the electronic parts to simultaneously activate the electronic parts.

In the configuration described in JP-A-2004-328505, however, since the electronic devices disposed in the substrate regions are simultaneously activated, the electronic devices can disadvantageously interfere with each other. For example, when the electronic devices include integrated circuits each of which is connected to a piezoelectric resonator element, the piezoelectric resonator elements may interfere with each other, resulting in a change in resonant frequency of the piezoelectric resonator elements and a difficulty in performing an appropriate test in some cases.

### SUMMARY

An advantage of some aspects of the invention is to provide, with respect to an electronic part formed on each substrate region of a sheet substrate by disposing an electronic device in the substrate region, a sheet substrate, an electronic part, an electronic apparatus, a method for testing electronic parts, and a method for manufacturing electronic parts, that prevent the electronic parts from interfering with other electronic devices and allow the electronic parts to be readily tested.

The invention can be implemented in the form of the following application examples.

### Application Example 1

This application example is directed to a sheet substrate including a plurality of substrate regions arranged in a matrix, an electronic device disposed in each of the plurality of substrate regions, a first implementation electrode and a second implementation electrode disposed in each of the substrate regions and electrically connected to the electronic device, a plurality of first terminals to each of which the first implementation electrodes arranged in a row of a plurality of the substrate regions are connected in parallel to each other, and a plurality of second terminals to each of which the second implementation electrodes arranged in a column of a plurality of the substrate regions and capable of activating an arbitrary one of the electronic devices that is specified by selected ones of the first terminals and the second terminals.

Since the configuration described above allows an arbitrary electronic device to be selectively activated, electronic devices adjacent to each other will not interfere with each other. Further, since it is not necessary to allow a test probe or any other test component to come into contact with any of the electrodes disposed in a substrate region being tested, the sheet substrate allows the electronic device to be readily tested.

### Application Example 2

This application example is directed to the sheet substrate described in Application Example 1, further including a third implementation electrode and a fourth implementation electrode disposed in each of the plurality of substrate regions and electrically connected to the electronic device and a third terminal to which, among the plurality of substrate regions, the third and fourth implementation electrodes in a plurality of the substrate regions arranged in one direction in rows or columns adjacent to each other, specifically, the third implementation electrodes disposed in the plurality of the substrate regions contained in one of the arrangements and the fourth implementation electrodes disposed in the plurality of the substrate regions contained in the other arrangement are connected in parallel to each other.

According to the configuration described above, the third terminal connected to the third implementation electrode in an activated electronic device and the third terminal connected to the fourth implementation electrode in the activated electronic device differ from each other. The third implementation electrode and the fourth implementation electrode connected to the activated electronic device can therefore be electrically connected by using only the third terminals.

### Application Example 3

This application example is directed to the sheet substrate described in Application Example 1, wherein a fifth implementation electrode bonded to the electronic device is disposed in each of the plurality of substrate regions, and among the plurality of substrate regions, the second terminals connect the second and fifth implementation electrodes in a plurality of the substrate regions arranged in one direction in columns adjacent to each other, specifically, the second implementation electrodes disposed in the plurality of the substrate regions contained in one of the arrangements and the fifth implementation electrodes disposed in the plurality of the substrate regions contained in the other arrangement in parallel to each other.

According to the configuration described above, the second terminal to which the second implementation electrode in an activated electronic device is connected differs from the second terminal to which the fifth implementation electrode in the activated electronic device is connected. The second implementation electrode and the fifth implementation electrode connected to the activated electronic device can be electrically connected by using only the second terminals.

### Application Example 4

This application example is directed to an electronic part formed by disposing the electronic device in each of the plurality of substrate regions of the sheet substrate described in Application Example 1 and dividing the sheet substrate along the substrate regions into individual pieces.

From the same reason described in Application Example 1, the electronic devices in the electronic parts will not interfere with each other, and the electronic devices can therefore be readily tested.

### Application Example 5

This application example directed to an electronic apparatus in which the electronic part described in Application Example 4 is incorporated.

From the same reason described in Application Example 1, the electronic devices in the electronic apparatus will not interfere with each other, and the electronic devices can therefore be readily tested.

### Application Example 6

This application example is directed to a method for testing electronic parts formed on a sheet substrate having a plurality of substrate regions arranged in a matrix by disposing an electronic device in each of the plurality of substrate regions and disposing a first implementation electrode and a second implementation electrode electrically connected to the electronic device in each of the plurality of substrate regions, the electronic parts formed on the respective substrate regions of the sheet substrate, the method including connecting the first implementation electrodes in a row of a plurality of the substrate regions to the corresponding one of a plurality of first terminals, connecting the second implementation electrodes in a column of a plurality of the substrate regions to the corresponding one of a plurality of second terminals, and activating an arbitrary one of the electronic devices that is specified by selected ones of the first terminals and the second terminals.

From the same reason described in Application Example 1, the method for testing electronic parts prevents the electronic devices from interfering with each other and allows the electronic devices to be readily tested.

### Application Example 7

This application example is directed to a method for manufacturing electronic parts formed on a sheet substrate having a plurality of substrate regions arranged in a matrix by disposing an electronic device in each of the plurality of substrate regions and disposing a first implementation electrode and a second implementation electrode electrically connected to the electronic device in each of the plurality of substrate regions, the electronic parts formed on the respective substrate regions of the sheet substrate, the method including: disposing a plurality of first terminals to each of which the first implementation electrodes arranged in a row of a plurality of the substrate regions are connected in parallel to each other and disposing a plurality of second terminals to each of which the second implementation electrodes arranged in a column of a plurality of the substrate regions are connected in parallel to each other, activating an arbitrary one of the electronic devices that is specified by selected ones of the first and second terminals, and dividing the sheet substrate along the boundaries between the substrate regions.

From the same reason described in Application Example 1, the method for manufacturing electronic parts prevents the electronic devices from interfering with each other and allows the electronic devices to be readily tested.

### BRIEF DESCRIPTION OF THE DRAWINGS

The invention will be described with reference to the accompanying drawings, wherein like numbers reference like elements.

FIG. 1 is a circuit diagram of a sheet substrate according to a first embodiment.

FIG. 2 is a plan view showing the sheet substrate according to the first embodiment.

FIG. 3 is a cross-sectional view of the sheet substrate taken along the line A-A in FIG. 2.

FIG. 4 is a bottom view of the sheet substrate according to the first embodiment.

FIG. 5 is an enlarged view of the portion surrounded by the dashed line in FIG. 2.

FIG. 6 is a schematic view of an electronic part according to the first embodiment.

FIG. 7 is a circuit diagram of a sheet substrate according to a second embodiment.

FIG. 8 shows a circuit diagram of a sheet substrate according to a third embodiment.

FIG. 9 is a plan view of the sheet substrate according to the third embodiment.

FIG. 10 is a schematic view of an electronic apparatus that accommodates the electronic part according to any of the embodiments described above.

### DESCRIPTION OF EXEMPLARY EMBODIMENTS

The invention will be described below in detail with reference to embodiments shown in the drawings. It is, however, noted that components described in the embodiments and the types, combinations, shapes, relative arrangements, and other characteristics of the components are not intended to limit the scope of the invention only thereto but are presented only by way of example of description unless otherwise stated.

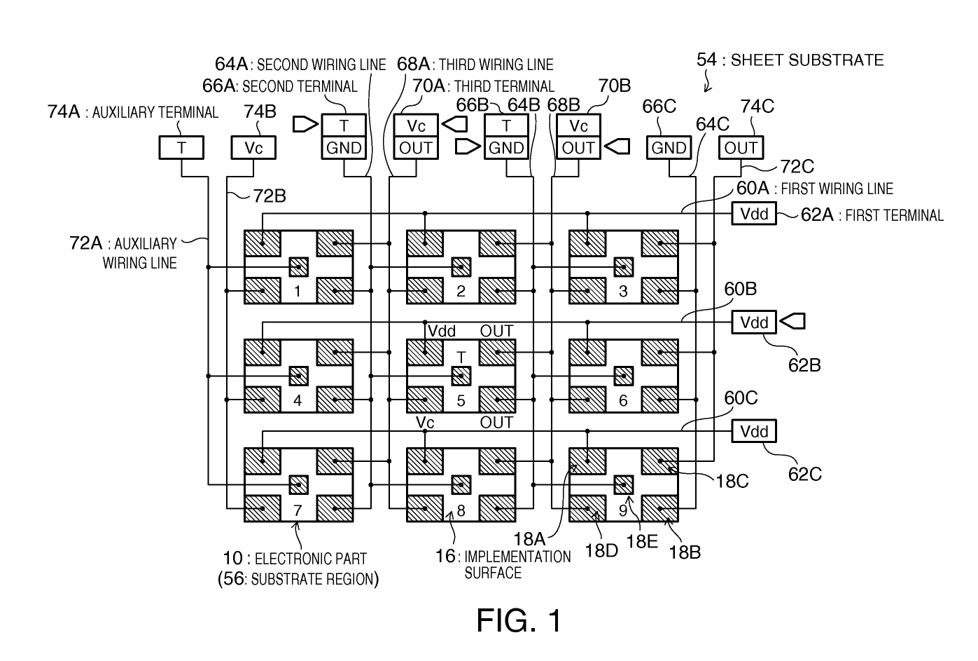

FIG. 1 is a circuit diagram of a sheet substrate according to a first embodiment. A sheet substrate 54 according to the first embodiment is a set of a plurality of electronic parts 10 (substrate regions 56) arranged in a matrix (3×3=9 in the present embodiment), and wiring lines are so arranged horizontally and vertically in the sheet substrate 54 that implementation electrodes 18A to 18E disposed in each of the electronic parts 10 are connected on a type basis. In FIG. 1, the electronic parts 10 are numbered (from first to ninth). Further, in FIG. 1, the vertical direction is called a row direction, and the horizontal direction is called a column direction.

In each of the electronic parts 10, an integrated circuit 50 is disposed, as will be described later, and the implementation electrodes 18A to 18E, which are electrically connected to the integrated circuit 50, are disposed on an implementation surface 16 of the electronic part 10. The implementation electrode 18A (first implementation electrode) is a power supply terminal (Vdd). The implementation electrode 18B (second implementation electrode) is a ground terminal (GND). The implementation electrode 18C (third implementation electrode) is an output terminal (OUT). The implementation electrode 18D (fourth implementation electrode) is an adjustment terminal (Vc), which will be described later. The implementation electrode 18E (fifth implementation electrode) is a temperature information output terminal (T), which will be described later.

First wiring lines 60A, 60B, and 60C each connect the implementation electrodes 18A in the electronic parts 10 in the same row in parallel to each other. The first wiring line 60A connects the first, second, and third implementation electrodes 18A in parallel to each other. The first wiring line 60B connects the fourth, fifth, and sixth implementation electrodes 18A in parallel to each other. The first wiring line 60C connects the seventh, eighth, and ninth implementation electrodes 18A in parallel to each other. The first wiring lines 60A, 60B, and 60C are connected to first terminals 62A, 62B, and 62C, respectively. The first terminals 62A, 62B, and 62C are controlled, for example, by external switching operation, and one of the terminals is turned on for power supply voltage application with the others turned off for termination of the power supply voltage application.

Second wiring lines 64A, 64B, and 64C each connect the implementation electrode 18B in the electronic parts 10 in the same column and the implementation electrode 18E in the electronic parts 10 in the same column in parallel to each other. Among the electronic parts 10, each of the second wiring lines 64A and 64B connects the implementation electrodes 18B and 18E in the electronic parts 10 arranged in one direction in the columns adjacent to each other, specifically, the implementation electrodes 18B disposed in the electronic parts 10 contained in one of the arrangements and the implementation electrodes 18E disposed in the electronic parts 10 contained in the other arrangement in parallel to each other.

The second wiring line 64A therefore connects the implementation electrodes 18B in the first, fourth, and seventh electronic parts 10 and the implementation electrodes 18E in the second, fifth, and eighth electronic parts 10 in parallel to each other. Similarly, the second wiring line 64B connects the implementation electrodes 18B in the second, fifth, and eighth electronic parts 10 and the implementation electrodes 18E in the third, sixth, and ninth electronic parts 10 in parallel to each other. On the other hand, the second wiring line 64C connects the implementation electrodes 18B in the third, sixth, and ninth electronic parts 10 in parallel to each other.

The second wiring lines 64A, 64B, and 64C are connected to second terminals 66A, 66B, and 66C, respectively. The second terminals 66A, 66B, and 66C are controlled, for example, by external switching operation, and one of the terminals is turned on to be grounded with the others turned off to be ungrounded. Further, an external terminal (not shown) for acquiring temperature information outputted through the implementation electrode 18E can be connected to each of the second terminals 66A and 66B.

Third wiring lines 68A and 68B each connect the implementation electrode 18C in the electronic parts 10 in the same column and the implementation electrode 18D in the electronic parts 10 in the same column in parallel to each other. Among the electronic parts 10, each of the third wiring lines 68A and 68B connects the implementation electrodes 18C and 18D in the electronic parts 10 arranged in one direction in the columns adjacent to each other, specifically, the implementation electrodes 18C disposed in the electronic parts 10 contained in one of the arrangements and the implementation electrodes 18D disposed in the electronic parts 10 contained in the other arrangement in parallel to each other.

The third wiring line 68A therefore connects the implementation electrodes 18C in the first, fourth, and seventh electronic parts 10 and the implementation electrodes 18D in the second, fifth, and eighth electronic parts 10 in parallel to each other. Similarly, the third wiring line 68B connects the implementation electrodes 18C in the second, fifth, and eighth electronic parts 10 and the implementation electrodes 18D in the third, sixth, and ninth electronic parts 10 in parallel to each other.

The third wiring lines 68A and 68B are connected to third terminals 70A and 70B, respectively. An external terminal (not shown) for extracting an output through the implementation electrode 18C or an external terminal (not shown) for applying an adjustment voltage to the implementation electrode 18D can be connected to each of the third terminals 70A and 70B.

An auxiliary wiring line 72A connects the implementation electrodes 18E in the first, fourth, and seventh electronic parts 10 in parallel to each other. An auxiliary wiring line 72B connects the implementation electrodes 18D in the first, fourth, and seventh electronic parts 10 in parallel to each other. An auxiliary wiring line 72C connects the implementation electrodes 18C in the third, sixth, and ninth electronic parts 10 in parallel to each other.

The auxiliary wiring lines 72A, 72B, and 72C are connected to auxiliary terminals 74A, 74B, and 74C, respectively. An external terminal (not shown) for acquiring temperature information outputted through the implementation electrode 18E is connected to the auxiliary terminal 74A. An external terminal (not shown) for applying an adjustment voltage to the implementation electrode 18D is connected to the auxiliary terminal 74B. An external terminal (not shown) for extracting an output through the implementation electrode 18C is connected to the auxiliary terminal 74C.

Each of the electronic parts 10 is activated when a power supply voltage is applied to the implementation electrode 18A and the implementation electrode 18B is grounded. For example, to activate the fifth electronic part 10, the first terminal 62B (indicated by an arrow in FIG. 1) and the second terminal 66B (indicated by an arrow in FIG. 1) are turned on, as shown in FIG. 1. At this point, the power supply voltage is also applied through the first terminal 62B to the fourth and sixth electronic parts 10, which are not activated because they are not grounded.

Further, the fifth electronic part 10 is connected to the second terminal 66A, the third terminal 70A, and the third terminal 70B. The following operation can therefore be performed: Temperature information associated with the fifth electronic part 10 is extracted through the second terminal 66A (indicated by an arrow in FIG. 1); an adjustment voltage is applied to the fifth electronic part 10 through the third terminal 70A (indicated by an arrow in FIG. 1); and an output from the fifth electronic part 10 is extracted through the third terminal 70B (indicated by an arrow in FIG. 1).

In the configuration described above, when the first terminal 62B is turned off and the first terminal 62A (62C) is turned on, the fifth electronic part 10 stops operating and the second (eighth) electronic part 10 can be activated. The extraction of temperature information, the application of an adjustment voltage, and the detection of an output from the electronic part 10 can then be performed in the same arrangement described above.

Further, when the first terminal 62B is turned on, the second terminal 66B is turned off, and the second terminal 66A (66C) is turned on, the fifth electronic part 10 stops operating and the fourth (sixth) electronic part 10 can be activated. At this point, the extraction of temperature information, the application of an adjustment voltage, and the extraction of an output from the electronic part 10 can be performed by switching the connection destinations of the external terminal (not shown) for extracting temperature information, the external terminal (not shown) for applying an adjustment voltage, and the external terminal (not shown) for extracting an output from the fourth (sixth) electronic part 10 to the terminals to the left (right) of the fifth electronic part 10. The sheet substrate 54 according to the present embodiment therefore allows all the electronic parts 10 to be individually activated for a variety of tests by arbitrarily selecting terminals to be turned on from the first terminals 62A to 62C and the second terminals 66A to 66C.

As described above, in the present embodiment, since an arbitrary electronic part 10 (integrated circuit 50) is selectively activated, electronic parts 10 adjacent to each other will not interfere with each other. Further, since it is not necessary to allow a test probe or any other component to come into contact with each of the implementation electrodes 18A to 18E disposed on an electronic part 10 (substrate region 56) being tested, the electronic part 10 (integrated circuit 50) on the sheet substrate 54 can be readily tested.

Each of the second terminals 66A and 66B is not grounded or used for temperature information acquisition at the same time. That is, the second terminal to which the implementation electrode 18B in an activated electronic part 10 (integrated circuit 50) is connected differs from the second terminal to which the implementation electrode 18E in the activated electronic part 10 is connected. The implementation electrodes 18B and 18E connected to an activated electronic part 10 can therefore be electrically connected by using only the second terminals.

Similarly, each of the third terminals 70A and 70B is not grounded or used for adjustment voltage application at the same time. That is, the third terminal to which the implementation electrode 18C in an activated electronic part 10 (integrated circuit 50) is connected differs from the third terminal to which the implementation electrode 18D in the activated electronic part 10 is connected. The implementation electrodes 18C and 18D connected to an activated electronic part 10 (integrated circuit 50) can therefore be electrically connected by using only the third terminals.

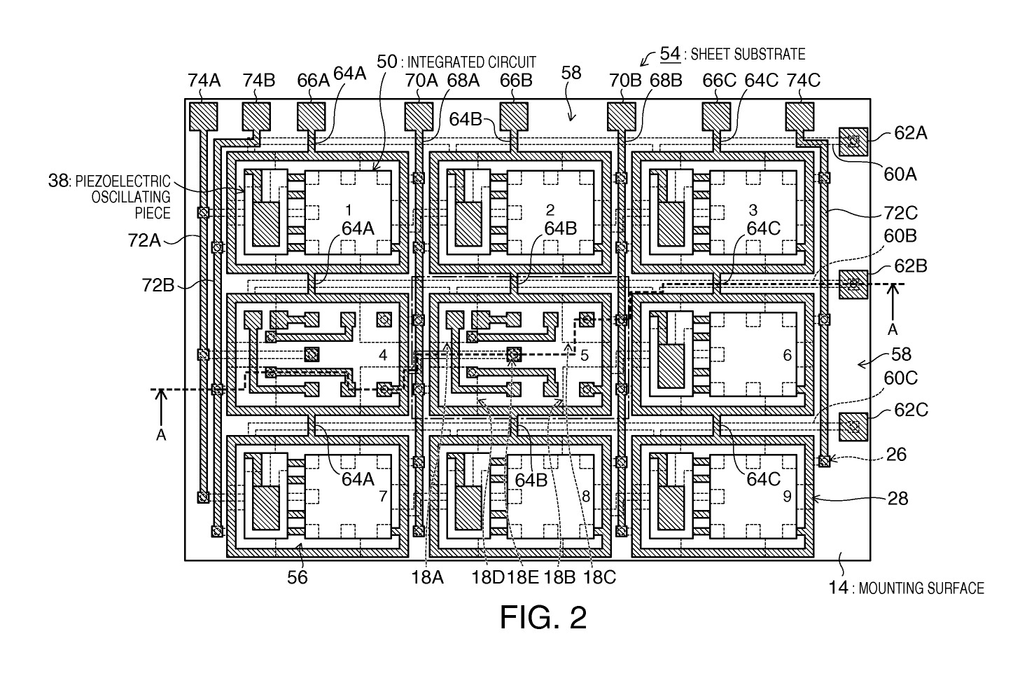

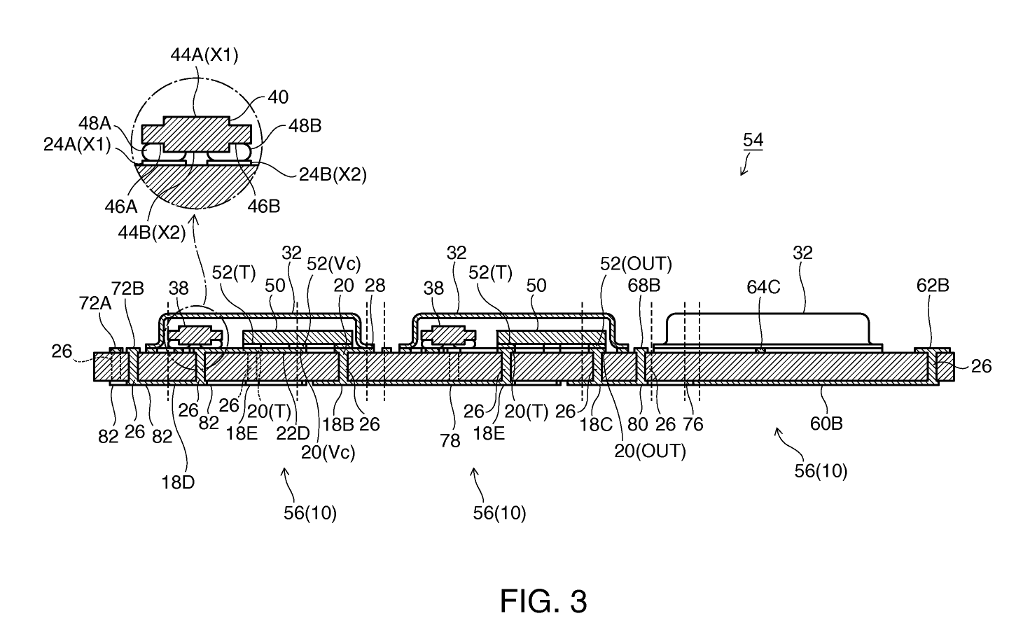

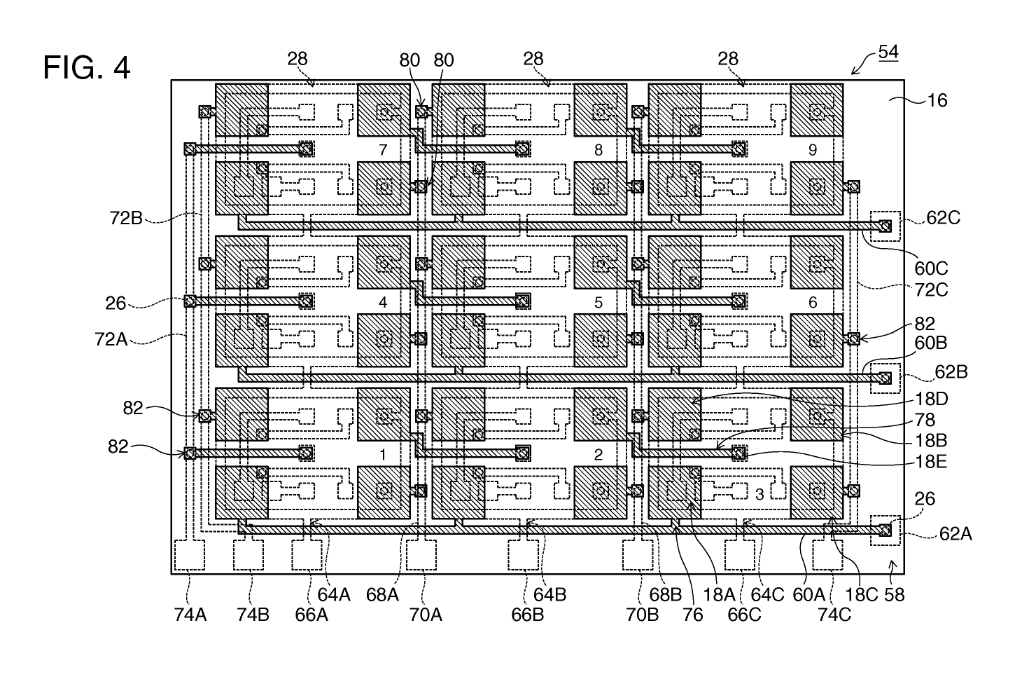

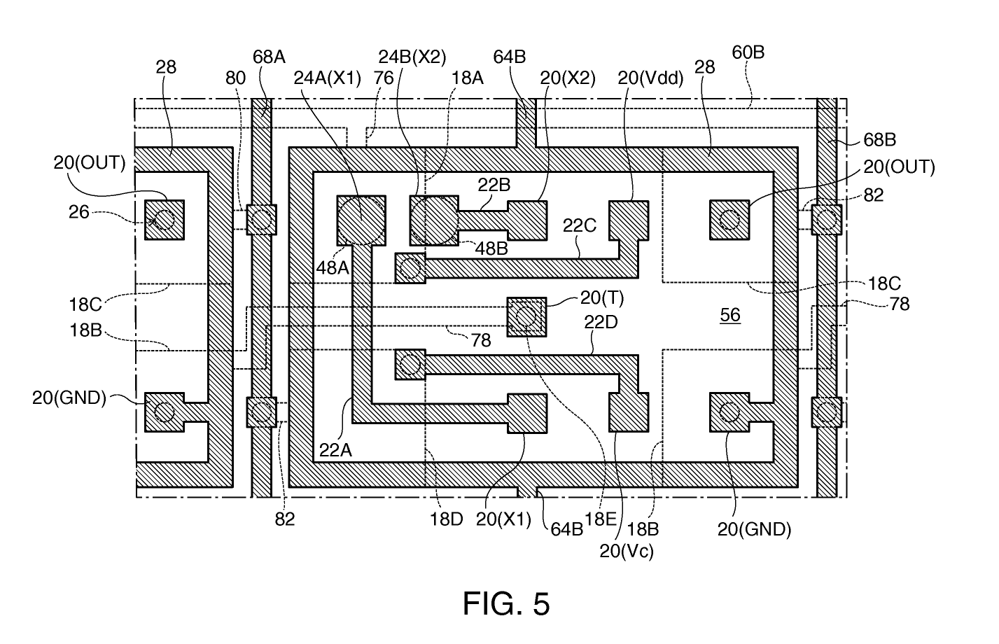

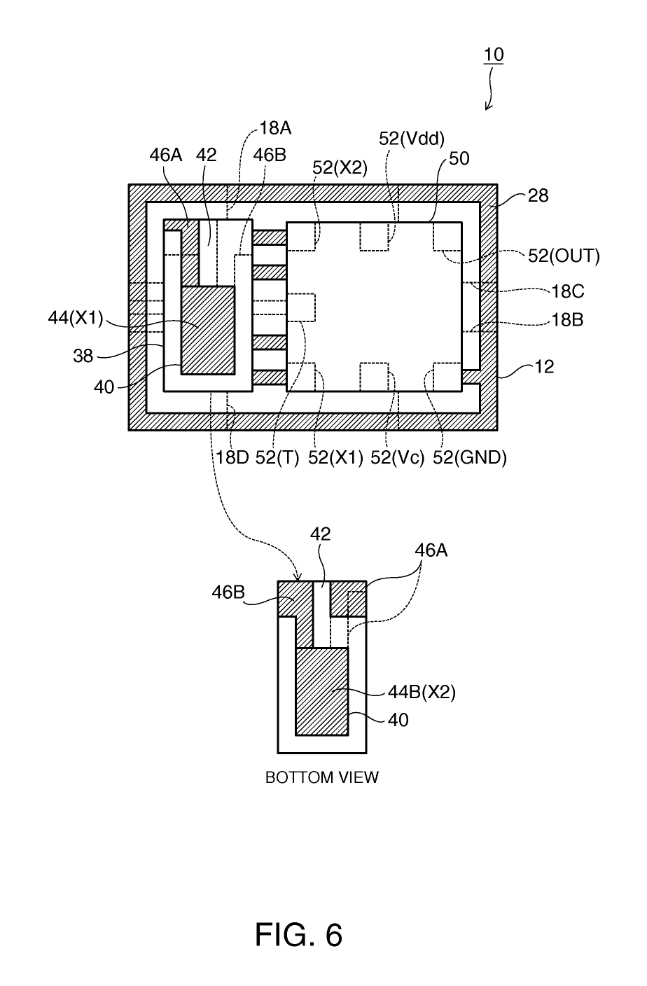

A description will next be made of the structure of the sheet substrate 54 configured based on the wiring diagram shown in FIG. 1 and the structure of a plurality of electronic parts 10 formed on the sheet substrate 54. FIG. 2 is a plan view showing the sheet substrate according to the first embodiment. FIG. 3 is a cross-sectional view of the sheet substrate taken along the line A-A in FIG. 2. FIG. 4 is a bottom view of the sheet substrate according to the first embodiment. FIG. 5 is an enlarged view of the portion surrounded by the dashed line in FIG. 2. FIG. 6 is a schematic view of an electronic part according to the present embodiment. In FIG. 2, no cap 32 is shown, and no piezoelectric resonator element 38 or integrated circuit 50 is shown in part of the substrate regions 56.

The sheet substrate 54 according to the present embodiment is made of a ceramic material or any other suitable insulating material and has a plurality of substrate regions 56 arranged in a matrix (3×3=9) and a terminal region 58 disposed around the substrate regions 56, as shown in FIG. 2. The substrate regions 56 are not in contact with each other but separated from each other by a predetermined distance, and the first wiring lines 60A to 60C, the second wiring lines 64A to 64C, and the third wiring lines 68A and 68B are disposed between the substrate regions 56.

A piezoelectric resonator element 38 and an integrated circuit 50 are disposed in each of the substrate regions 56 on the upper surface (mounting surface 14) of the sheet substrate 54, and the implementation electrodes 18A to 18E are disposed in each of the substrate regions 56 on the rear surface (implementation surface 16) of the sheet substrate 54. As described above, on the sheet substrate 54 according to the present embodiment, the electronic part 10 according to the present embodiment is formed in each of the substrate regions 56, and the sheet substrate 54 is divided along the boundaries between the substrate regions 56 into individual electronic parts 10, each of which is formed based on a base substrate 12.

Each of the electronic parts 10 has a form in which the piezoelectric resonator element 38 and the integrated circuit 50 are arranged side by side on the base substrate 12 and a cap 32 (FIG. 3) that accommodates the piezoelectric resonator element 38 and the integrated circuit 50 is bonded to the base substrate 12, as shown in FIG. 6 and other figures. The electronic part 10 is therefore a piezoelectric device that oscillates by itself when it externally receives electric power.

The piezoelectric resonator element 38 is made of quartz or any other piezoelectric material. In the present embodiment, the piezoelectric resonator element 38 is, for example, a thickness-shear resonator element using a quartz AT-cut substrate. The piezoelectric resonator element 38 includes an oscillating portion 40 (see enlarged view in FIG. 3), which oscillates in a thickness-shear mode, and a mount portion 42, which is bonded to the base substrate 12. An excitation electrode 44A (X1) is disposed on the upper surface of the oscillating portion 40, and an excitation electrode 44B (X2) is disposed on the lower surface of the oscillating portion 40. A drawn electrode 46A is drawn from the excitation electrode 44A, and a drawn electrode 46B is drawn from the excitation electrode 44B. The drawn electrode 46B is drawn to the lower surface of the mount portion 42. The drawn electrode 46A is drawn to the lower surface of the mount portion 42 via the upper surface and a side surface of the mount portion 42. The piezoelectric resonator element 38 can alternatively be a tuning-fork resonator element, a double-ended tuning-fork resonator element, a SAW resonance piece, a gyro resonator element, or any other suitable resonator element.

The integrated circuit 50 is an electronic device formed of an oscillation circuit that drives the piezoelectric resonator element 38 as an oscillation source, a temperature compensation circuit that compensates an oscillation signal from the oscillation circuit in terms of temperature, and other circuits integrated with each other. Pad electrodes 52 are disposed on an active surface (lower surface) of the integrated circuit 50. The pad electrodes 52 include connection terminals (X1, X2) electrically connected to the piezoelectric resonator element 38, a power supply terminal (Vdd) that externally receives electric power, a ground terminal (GND), and an output terminal (OUT) through which an output signal is outputted. As another pad electrode 52, an adjustment voltage input terminal (Vc) for inputting an adjustment voltage for oscillation frequency adjustment of the output signal from the oscillation circuit built in the integrated circuit 50 is disposed. The integrated circuit 50 further has a built-in thermistor, based on which the temperature information is generated. To output the temperature information, a temperature information output terminal (T) is disposed as another pad electrode 52 on the integrated circuit 50.

The base substrate 12 has a mounting surface 14, on which the piezoelectric resonator element 38 and the integrated circuit 50 are mounted, and an implementation surface 16, which faces away from the mounting surface 14. Mount electrodes 24A and 24B are disposed on the mounting surface 14 of the base substrate 12 in the positions facing the drawn electrodes 46A and 46B, as shown in FIG. 5. Further, connection electrodes 20 (X1, X2, Vdd, GND, OUT, Vc, and T) are disposed on the mounting surface 14 in the positions facing the pad electrodes 52. On the other hand, the implementation electrodes 18A (Vdd), 18B (GND), 18C (OUT), 18D (Vc), and 18E (T) are disposed along the circumferential edge of the lower surface or the implementation surface 16 of the base substrate 12, as shown in FIGS. 4 and 5.

The mount electrode 24A (X1) and the connection electrode 20 (X1) are electrically connected to each other via a routing electrode 22A, and the mount electrode 24B (X2) and the connection electrode 20 (X2) are also electrically connected to each other via a routing electrode 22B, as shown in FIG. 5.

A routing electrode 22C extends from the connection electrode 20 (Vdd). The routing electrode 22C extends to a position immediately above the implementation electrode 18A and is electrically connected to the implementation electrode 18A via a through electrode 26, which passes through the base substrate 12. The connection electrode 20 (Vdd) is therefore electrically connected to the implementation electrode 18A.

The connection electrode 20 (GND) is disposed in a position immediately above the implementation electrode 18B and electrically connected to the implementation electrode 18B via a through electrode 26. The connection electrode 20 (OUT) is disposed in a position immediately above the implementation electrode 18C and electrically connected to the implementation electrode 18C via a through electrode 26.

A routing electrode 22D extends from the connection electrode 20 (Vc). The routing electrode 22D extends to a position immediately above the implementation electrode 18D and is electrically connected to the implementation electrode 18D via a through electrode 26. The connection electrode 20 (Vc) is therefore electrically connected to the implementation electrode 18D.

The connection electrode 20 (T) is disposed in a position immediately above the implementation electrode 18E and electrically connected to the implementation electrode 18E via a through electrode 26. A frame-shaped metalized portion 28 is so positioned on the mounting surface 14 of the base substrate 12 that the metalized portion 28 surrounds the piezoelectric resonator element 38 and the integrated circuit 50. The metalized portion 28 is connected to the connection electrode 20 (GND). The metalized portion 28 is therefore electrically connected to the implementation electrode 18B. The cap 32 (FIG. 3), which is made of a metal, is bonded to the base substrate 12 via the metalized portion 28, which works as a bonding surface. The cap 32 therefore not only hermetically seals the piezoelectric resonator element 38 and the integrated circuit 50 but also electrostatically shields the accommodation space formed by the cap 32 against the environment, whereby the amount of electric disturbance to the piezoelectric resonator element 38 and the integrated circuit 50 can be reduced.

The piezoelectric resonator element 38 is boned onto the base substrate 12 in a form in which the drawn electrode 46A and the mount electrode 24A are bonded to each other with a conductive adhesive 48A and the drawn electrode 46B and the mount electrode 24B are bonded to each other with a conductive adhesive 48B, as shown in FIGS. 3 and 5. As a result, the piezoelectric resonator element 38 is supported in the form of a cantilever by the base substrate 12 with the mount portion 42 (FIG. 6) acting as a fixed end and electrically connected to the mount electrodes 24A and 24B.

Further, the integrated circuit 50 is electrically connected to the connection electrodes 20, the mount electrodes 24A and 24B, and the implementation electrodes 18A to 18E by bonding the pad electrodes 52 (X1, X2, Vdd, GND, OUT, Vc, and T) on the integrated circuit 50 to the connection electrodes 20 (X1, X2, Vdd, GND, OUT, Vc, and T). The integrated circuit 50 is therefore driven when it receives electric power through the implementation electrode 18A (Vdd) with the implementation electrode 18B (GND) grounded. When the integrated circuit 50 applies an AC voltage to the piezoelectric resonator element 38 via the pad electrodes 52 (X1, X2), the piezoelectric resonator element 38 oscillates at a predetermined resonant frequency, and the integrated circuit 50 can output an oscillation signal associated with the oscillation through the implementation electrode 18C (OUT). Further, an adjustment voltage can be applied to the integrated circuit 50 through the implementation electrode 18D (Vc), and temperature information based on the thermistor can be outputted through the implementation electrode 18E.

The first wiring lines 60A, 60B, and 60C are disposed on the implementation surface 16 of the sheet substrate 54, extend in the column direction of the arrangement of the substrate regions 56, and connect the implementation electrodes 18A in the same row in parallel to each other, as shown in FIGS. 2 and 4.

The first wiring line 60A is disposed along the arrangement of the first, second, and third substrate regions 56 and connected to the implementation electrode 18A in each of the first, second, and third substrate regions 56 via a routing electrode 76.

The first wiring line 60B is disposed in the region between the arrangement of the first, second, and third substrate regions 56 and the arrangement of the fourth, fifth, and sixth substrate regions 56 and connected to the implementation electrode 18A in each of the fourth, fifth, and sixth substrate regions 56 via a routing electrode 76.

The first wiring line 60C is disposed in the region between the arrangement of the fourth, fifth, and sixth substrate regions 56 and the arrangement of the seventh, eighth, and ninth substrate regions 56 and connected to the implementation electrode 18A in each of the seventh, eighth, and ninth substrate regions 56 via a routing electrode 76.

The first terminals 62A, 62B, and 62C are disposed in the terminal region 58 on the upper surface of the sheet substrate 54 and electrically connected to the first wiring lines 60A, 60B, and 60C, respectively, via through electrodes 26.

As shown in FIGS. 2 and 4, the second wiring lines 64A, 64B, and 64C are so disposed on the mounting surface 14 of the sheet substrate 54 that they serially connect the metalized portions 28 in the same column (see FIG. 5). The second wiring lines 64 thus connect the implementation electrodes 18B as follows: The second wiring line 64A connects the implementation electrodes 18B in the first, fourth, and seventh substrate regions 56 in parallel to each other; the second wiring line 64B connects the implementation electrodes 18B in the second, fifth, and eighth substrate regions 56 in parallel to each other; and the second wiring line 64C connects the implementation electrodes 18B in the third, sixth, and ninth substrate regions 56 in parallel to each other.

Each of the implementation electrodes 18E is electrically connected to the implementation electrode 18B in the substrate region 56 located to the left of the implementation electrode 18E via a routing electrode 78, as shown in FIGS. 4 and 5. As a result, the second wiring line 64A electrically connects the implementation electrodes 18E in the second, fifth, and eighth substrate regions 56 in parallel to each other, and the second wiring line 64B electrically connects the implementation electrodes 18E in the third, sixth, and ninth substrate regions 56 in parallel to each other. The second wiring lines 64A, 64B, and 64C extend to the terminal region 58 and are connected to the second terminals 66A, 66B, and 66C, respectively.

The third wiring line 68A is disposed on the mounting surface 14 of the sheet substrate 54 in the region between the arrangement of the first, fourth, and seventh substrate regions and the arrangement of the second, fifth, and eighth substrate regions 56 and extends in the row direction, as shown in FIG. 2.

The third wiring line 68A electrically connects the implementation electrodes 18C in the first, fourth, and seventh substrate regions 56 to the implementation electrodes 18D in the second, fifth, and eighth substrate regions 56 in parallel to each other via routing electrodes 80 and through electrodes 26, as shown in FIG. 4.

The third wiring line 68B is disposed on the mounting surface 14 of the sheet substrate 54 in the region between the arrangement of the second, fifth, and eighth substrate regions 56 and the arrangement of the third, sixth, and ninth substrate regions 56 and extends in the row direction, as shown in FIG. 2.

The third wiring line 68B electrically connects the implementation electrodes 18C in the second, fifth, and eighth substrate regions 56 to the implementation electrodes 18D in the third, sixth, and ninth substrate regions 56 in parallel to each other via routing electrodes 80 and through electrodes 26, as shown in FIG. 4.

The third wiring lines 68A and 68B extend to the terminal region 58 and are connected to the third terminals 70A and 70B, respectively.

The auxiliary line 72A is disposed on the mounting surface 14 of the sheet substrate 54 and extends in the row direction along the arrangement of the first, fourth, and seventh substrate regions 56, as shown in FIG. 2. The auxiliary line 72A electrically connects the implementation electrodes 18E in the first, fourth, and seventh substrate regions 56 in parallel to each other via routing electrodes 82 and through electrodes 26, as shown in FIG. 4.

The auxiliary line 72B is disposed in the region between the auxiliary line 72A and the arrangement of the first, fourth, and seventh substrate regions 56 and extends in the row direction, as shown in FIG. 2. The auxiliary line 72B electrically connects the implementation electrodes 18D in the first, fourth, and seventh substrate regions 56 in parallel to each other via routing electrodes 82 and through electrodes 26, as shown in FIG. 4.

The auxiliary line 72C is disposed on the mounting surface 14 of the sheet substrate 54 and extends in the row direction along the arrangement of the third, sixth, and ninth substrate regions 56, as shown in FIG. 2. The auxiliary line 72C electrically connects the implementation electrodes 18C in the third, sixth, and ninth substrate regions 56 in parallel to each other via routing electrodes 82 and through electrodes 26, as shown in FIG. 4. The auxiliary lines 72A, 72B, and 72C extend to the terminal region 58 and are connected to the auxiliary terminals 74A, 74B, and 74C, respectively.

In FIG. 3, the left (fourth) substrate region 56 (electronic part 10) shows a state in which the pad electrode 52 (Vc) on the integrated circuit 50 is electrically connected to the auxiliary line 72B (auxiliary terminal 74B) via the connection electrode 20 (Vc), the routing electrode 22D, the through electrode 26, the implementation electrode 18D, the routing electrode 82, and the through electrode 26. The left (fourth) substrate region 56 further shows a state in which the pad electrode 52 (T) on the integrated circuit 50 is electrically connected to the auxiliary line 72A (auxiliary terminal 74A) via the connection electrode 20 (T), the through electrode 26, the implementation electrode 18E, the routing electrode 82, and the through electrode 26.

The central (fifth) substrate region 56 (electronic part 10) in FIG. 3 shows a state in which the pad electrode 52 (T) on the integrated circuit 50 is electrically connected to the metalized portion 28 (second wiring line 64A, second terminal 66A) via the connection electrode 20 (T), the through electrode 26, the implementation electrode 18E, the routing electrode 78, the implementation electrode 18B in the fourth substrate electrode 56, the through electrode 26, and the connection electrode 20 (GND). The central (fifth) substrate region 56 further shows a state in which the pad electrode 52 (OUT) on the integrated circuit 50 is electrically connected to the third wiring line 68B (third terminal 70B) via the connection electrode 20 (OUT), the through electrode 26, the implementation electrode 18C, the routing electrode 80, and the through electrode 26.

The right portion of FIG. 3, which is a cutaway view which shows the region between the third substrate region 56 and the sixth substrate region 56 and in which the second wiring line 64C is cut, shows a state in which the first terminal 62B is electrically connected to the implementation electrode 18A in the sixth substrate region 56 (not shown in FIG. 3) via the through electrode 26, the first wiring line 60B, and the routing electrode 76.

The sheet substrate 54 according to the present embodiment may be formed by forming through holes for forming the through electrodes 26 through a pre-sintered ceramic substrate having a plurality of substrate regions 56 and a terminal region 58, sintering the ceramic substrate, filling the through holes with the through electrodes 26, and forming a variety of wiring lines and electrodes, for example, in a sputtering process.

Manufacturing steps of the electronic part 10 according to the present embodiment include implementing the piezoelectric resonator element 38, the integrated circuit 50, and the cap 32 in each of the substrate regions 56 of the sheet substrate 54. The integrated circuits 50 disposed in the substrate regions 56 (electronic parts 10) are then activated one by one by arbitrarily selecting terminals from the first terminals 62A, 62B, and 62C and the second terminals 66A, 66B, and 66C disposed in the terminal region 58. An oscillation signal and temperature information outputted from an activated integrated circuit 50 are examined, and an adjustment voltage is applied to the integrated circuit 50 for a variety of adjustments. If the integrated circuit 50 or the piezoelectric resonator element 38 connected thereto is defective, the electronic part 10 formed on the defective substrate region 56 is, of course, removed. The sheet substrate 54 can then be divided along the boundaries between the substrate regions 56 into individual electronic parts 10.

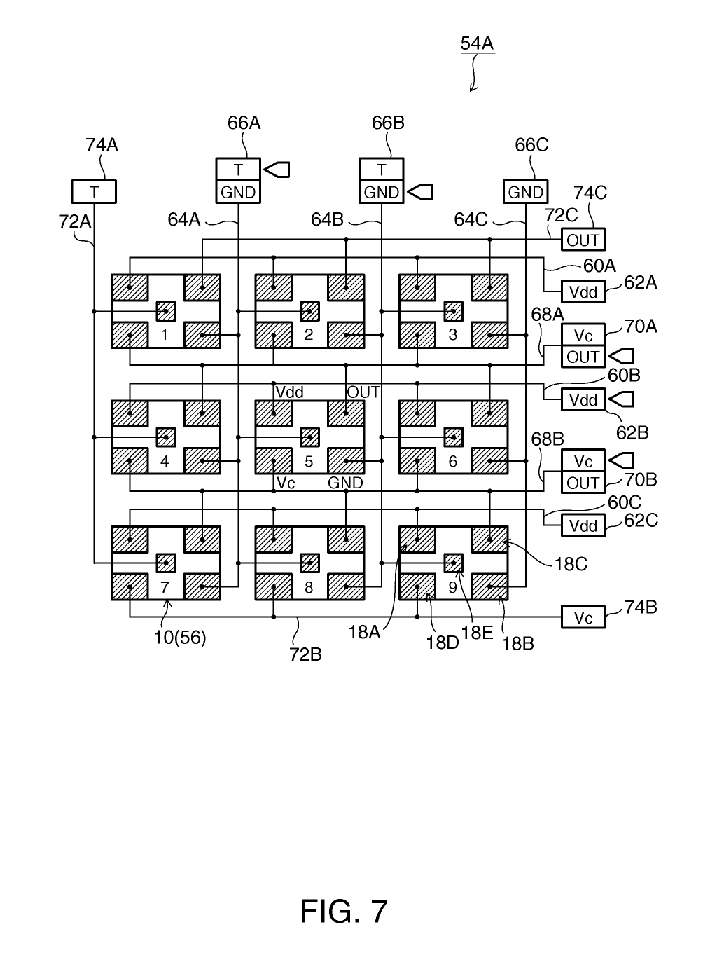

FIG. 7 is a circuit diagram of a sheet substrate according to a second embodiment. In the following description, the same components as those in the embodiment described above have the same reference numbers, and no description thereof will be made unless necessary.

A sheet substrate 54A according to the second embodiment differs from the sheet substrate 54 according to the first embodiment in terms of the orientation of the third wiring lines. That is, among the electronic parts 10 (substrate regions 56), the third wiring lines 68A and 68B connect the implementation electrodes 18C and 18D in the electronic parts 10 arranged in one direction in rows adjacent to each other, specifically, the implementation electrodes 18C disposed in the electronic parts 10 contained in one of the arrangements and the implementation electrodes 18D disposed in the electronic parts 10 contained in the other arrangement in parallel to each other. The third wiring line 68A therefore connects the implementation electrodes 18D in the first, second, and third electronic parts 10 to the implementation electrodes 18C in the fourth, fifth, and sixth electronic parts 10 in parallel to each other. The third wiring line 68B connects the implementation electrodes 18D in the fourth, fifth, and sixth electronic parts 10 to the implementation electrodes 18C in the seventh, eighth, and ninth electronic parts 10 in parallel to each other.

Further, the auxiliary line 72B connects the implementation electrodes 18D in the seventh, eighth, and ninth electronic parts 10 in parallel to each other, and the auxiliary line 72C connects the implementation electrodes 18C in the first, second, and third electronic parts 10 in parallel to each other.

In correspondence with FIG. 2, the third wiring lines 68A and 68B and the auxiliary lines 72B and 72C may be disposed on the mounting surface 14 of the sheet substrate 54A (sheet substrate 54). The third wiring line 68A may be disposed in the region between the arrangement of the first, second, and third substrate regions 56 and the arrangement of the fourth, fifth, and sixth substrate regions 56, and the third wiring line 68B may be disposed in the region between the arrangement of the fourth, fifth, and sixth substrate regions 56 and the arrangement of the seventh, eighth, and ninth substrate regions 56. The auxiliary line 72B may be disposed along the arrangement of the seventh, eighth, and ninth substrate regions 56, and the auxiliary line 72C may be disposed along the arrangement of the first, second, and third substrate regions 56. A method for testing the electronic parts 10 arranged on the sheet substrate 54A according to the second embodiment is the same as the method described in the first embodiment, and no description of the test method according to the second embodiment will be made.

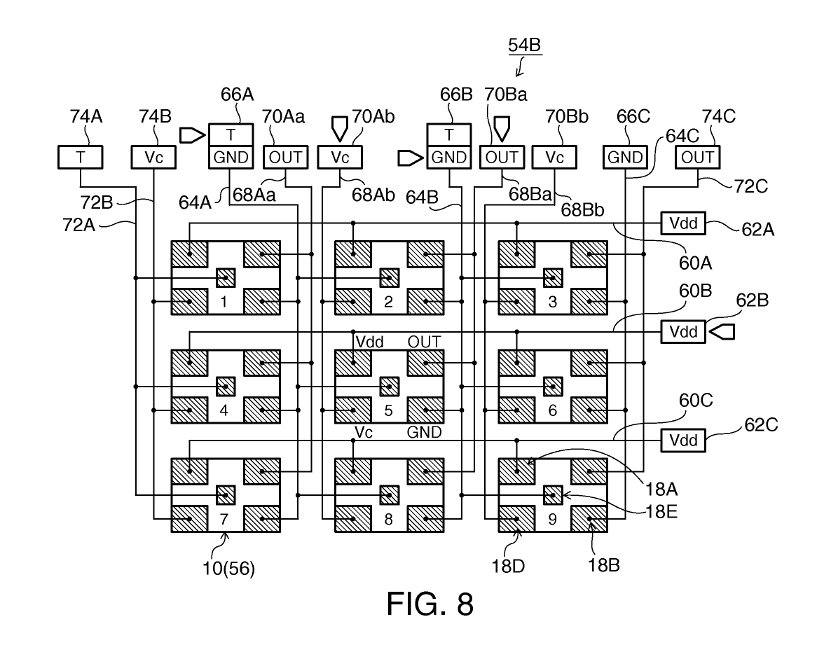

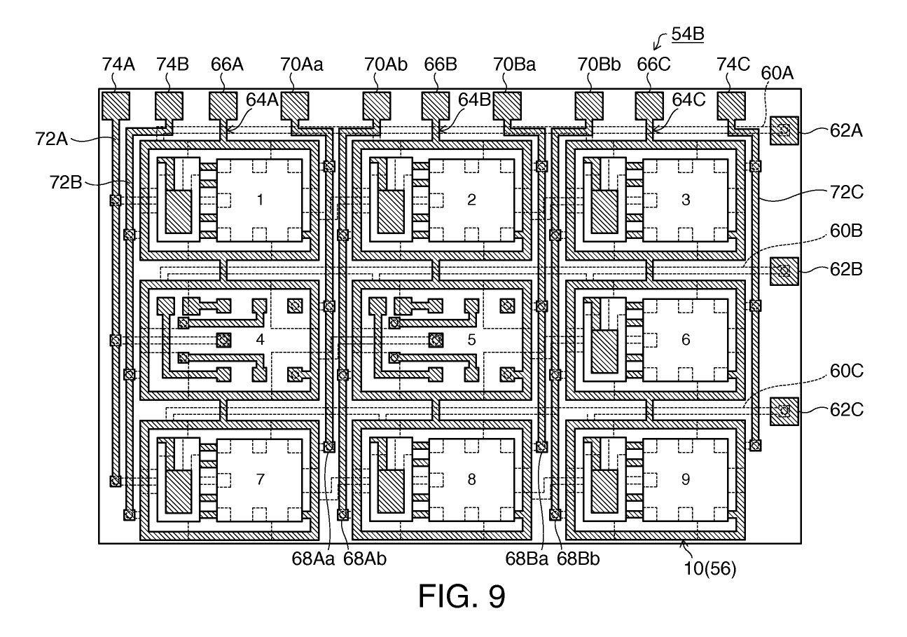

FIG. 8 shows a circuit diagram of a sheet substrate according to a third embodiment, and FIG. 9 is a plan view of the sheet substrate according to the third embodiment. On a sheet substrate 54B according to the third embodiment, the third wiring lines 68A and 68B are divided into third wiring lines 68Aa and 68Ab and third wiring lines 68Ba and 68Bb, respectively.

The third wiring line 68Aa connects the implementation electrodes 18C in the first, fourth, and seventh electronic parts 10 (substrate regions 56) in parallel to each other and has an end connected to a third terminal 70Aa. The third wiring line 68Ab connects the implementation electrodes 18D in the second, fifth, and eighth electronic parts 10 in parallel to each other and has an end connected to a third terminal 70Ab.

The third wiring line 68Ba connects the implementation electrodes 18C in the second, fifth, and eighth electronic parts 10 in parallel to each other and has an end connected to a third terminal 70Ba. The third wiring line 68Bb connects the implementation electrodes 18D in the third, sixth, and ninth electronic parts 10 in parallel to each other and has an end connected to a third terminal 70Bb.

In the configuration described above, to activate the fifth electronic part 10, the first terminal 62B and the second terminal 66B are turned on. The temperature information associated with the fifth electronic part 10 can be acquired through the second terminal 66A. An adjustment voltage can be applied to the fifth electronic part 10 through the third terminal 70Ab. An output from the fifth electronic part 10 can be extracted through the third terminal 70Ba.

The third wiring lines 68Aa, 68Ab, 68Ba, and 68Bb may be disposed on the mounting surface 14 of the sheet substrate 54B, as shown in FIG. 9. The third wiring lines 68Aa and 68Ab may be disposed in parallel to each other in the region between the arrangement of the first, fourth, and seventh substrate regions 56 and the arrangement of the second, fifth, and eighth substrate regions 56. The third wiring lines 68Ba and 68Bb may be disposed in parallel to each other in the region between the arrangement of the second, fifth, and eighth substrate regions 56 and the arrangement of the third, sixth, and ninth substrate regions 56.

In the first and second embodiments, each of the third terminals 70A and 70B is used not only to extract an output from an electronic part 10 but also to apply an adjustment voltage to the electronic part 10. When an adjustment voltage is applied to an activated electronic part 10, the adjustment voltage is therefore also applied to the implementation electrode 18C in each of the other electronic parts 10 connected to the third terminal to which the activated electronic part 10 is connected, and the adjustment voltage may adversely affect the integrated circuit 50 in each of the other electronic parts 10. To address the problem, the wiring line for extracting an output from an electronic part 10 and the wiring line for applying an adjustment voltage is applied to the electronic part 10 are separately provided in the present embodiment.

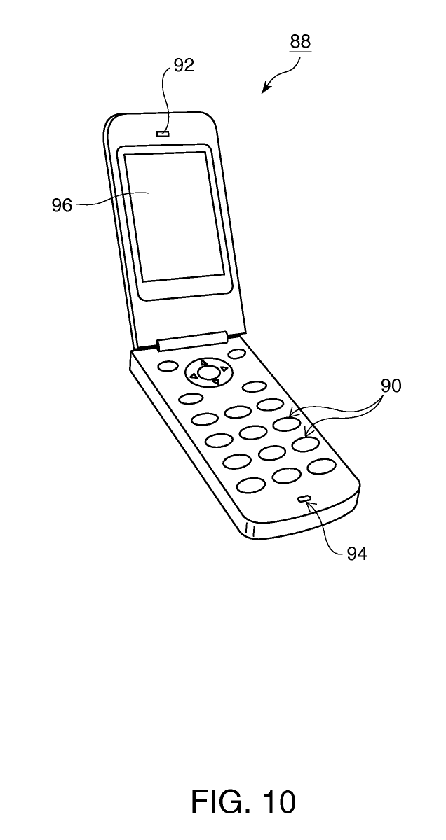

FIG. 10 is a schematic view of an electronic apparatus (mobile terminal) that accommodates the electronic part according to any of the embodiments described above. In FIG. 10, a mobile terminal 88 (including PHS) includes a plurality of operation buttons 90, a receiver 92, and a transmitter 94, and a display 96 is disposed in the region between the operation buttons 90 and the receiver 92. A recent mobile terminal 88 of this type also has a GPS capability. To this end, the mobile terminal 88 accommodates the electronic part 10 (piezoelectric device) according to any of the embodiments described above as a clock source in a GPS circuit.

An electronic apparatus that accommodates the electronic part 10 according to any of the embodiments described above is not limited to the mobile terminal 88 described above and can be used with an advanced mobile phone, a digital still camera, a personal computer, a laptop personal computer, a television receiver, a video camcorder, a video tape recorder, a car navigation system, a pager, an inkjet-type liquid ejection apparatus, an electronic notebook, a desktop calculator, an electronic game console, a word processor, a workstation, a TV phone, a security television monitor, electronic binoculars, a POS terminal, a medical apparatus (such as electronic thermometer, blood pressure gauge, blood sugar meter, electrocardiograph, ultrasonic diagnostic apparatus, and electronic endoscope), a fish finder, a variety of measuring apparatus, a variety of instruments (such as instruments in vehicles, airplanes, and ships), and a flight simulator.

The entire disclosure of Japanese Patent Application No. 2012-111168, filed May 15, 2012 is expressly incorporated by reference herein.

What is claimed is:

1. A sheet substrate comprising:
a plurality of substrate regions arranged in a first direction and a second direction;
electronic device mounting pads disposed in each of the substrate regions;
a first implementation electrode and a second implementation electrode connected to the electronic device mounting pads;
a plurality of first terminals to each of which the first implementation electrodes arranged in a row of a plurality of the substrate regions are connected in parallel to each other; and
a plurality of second terminals to each of which the second implementation electrodes arranged in a column of a plurality of the substrate regions are connected in parallel to each other.

2. The sheet substrate according to claim 1, further comprising:
a third implementation electrode and a fourth implementation electrode disposed in each of the substrate regions; and
a third terminal to which, among the substrate regions, the third and fourth implementation electrodes in a plurality of the substrate regions arranged in one direction in rows or columns adjacent to each other, specifically, the third implementation electrodes contained in one of the arrangements and the fourth implementation electrodes contained in the other arrangement are connected in parallel to each other.

3. The sheet substrate according to claim 1, further comprising
a fifth implementation electrode disposed in each of the substrate regions,
wherein among the substrate regions, the second and fifth implementation electrodes in a plurality of the substrate regions arranged in one direction in columns adjacent to each other, specifically, the second implementation electrodes contained in one of the arrangements and the fifth implementation electrodes contained in the other arrangement are connected in parallel to each other.

4. An electronic part formed by disposing an electronic device on the electronic device mounting pads in each of the substrate regions of the sheet substrate according to claim 1 and dividing the sheet substrate along the substrate regions into individual pieces.

5. An electronic part formed by disposing an electronic device on the electronic device mounting pads in each of the substrate regions of the sheet substrate according to claim 2 and dividing the sheet substrate along the substrate regions into individual pieces.

6. An electronic part formed by disposing an electronic device on the electronic device mounting pads in each of the substrate regions of the sheet substrate according to claim 3 and dividing the sheet substrate along the substrate regions into individual pieces.

7. An electronic apparatus in which the electronic part according to claim 4 is disposed.

8. An electronic apparatus in which the electronic part according to claim 5 is disposed.

9. An electronic apparatus in which the electronic part according to claim 6 is disposed.

10. A method for testing electronic parts including
a sheet substrate having
a plurality of substrate regions arranged in a matrix,
electronic device mounting pads disposed in each of the substrate regions,
a first implementation electrode and a second implementation electrode disposed in each of the substrate regions and connected to the electronic device mounting pads,
a plurality of first terminals to each of which the first implementation electrodes arranged in a row of a plurality of the substrate regions are connected in parallel to each other, and
a plurality of second terminals to each of which the second implementation electrodes arranged in a column of a plurality of the substrate regions are connected in parallel to each other, and
an electronic device disposed on the electronic device mounting pads,
the electronic parts formed on the respective substrate regions of the sheet substrate,
the method comprising
activating an arbitrary one of the electronic devices that is specified by selected ones of the first and second terminals and testing the activated electronic device.

11. A method for manufacturing electronic parts including
a sheet substrate having a plurality of substrate regions arranged in a matrix, electronic device mounting pads disposed in each of the substrate regions, and a first implementation electrode and a second implementation electrode disposed in each of the substrate regions and connected to the electronic device mounting pads, and
an electronic device disposed on the electronic device mounting pads,
the electronic parts formed on the respective substrate regions of the sheet substrate, the method comprising:
disposing a plurality of first terminals to each of which the first implementation electrodes arranged in a row of a plurality of the substrate regions are connected in parallel to each other and disposing a plurality of second terminals to each of which the second implementation electrodes arranged in a column of a plurality of the substrate regions are connected in parallel to each other;
activating an arbitrary one of the electronic devices that is specified by selected ones of the first and second terminals; and
dividing the sheet substrate along the substrate regions.
